(19) United States
(12) Patent Application Publication
(10) Pub. No.: US 2026/0309819 A1
(43) Pub. Date: Oct. 8, 2026

(54) SUPERCONDUCTING MAGNET APPARATUS AND MAGNETIC RESONANCE IMAGING APPARATUS

(71) Applicant: CANON MEDICAL SYSTEMS CORPORATION, Otawara-shi (JP)

(72) Inventors: Katsutoshi MIZUNO, Nasushiobara (JP); Kentaro KIKUCHI, Saitama (JP); Takehiro SHIBUYA, Nasushiobara (JP)

(73) Assignee: CANON MEDICAL SYSTEMS CORPORATION, Otawara-shi (JP)

(21) Appl. No.: 19/564,381

(22) Filed: Mar. 12, 2026

(30) Foreign Application Priority Data
Apr. 7, 2025 (JP) 2025-063130

(51) Int. Cl. G01R 33/3815; H01F 6/04; H01F 6/06

(52) U.S. Cl. CPC G01R 33/3815; H01F 6/04; H01F 6/06

(57) ABSTRACT

A superconducting magnet apparatus includes a vacuum vessel, a radiation shield, a static magnetic field coil, and a closed loop coil. The radiation shield is accommodated in the vacuum vessel. The static magnetic field coil is accommodated in the radiation shield and includes a high-temperature superconducting wire that is wound around a central axis of the vacuum vessel and excited by receiving a current supplied from an excitation power supply. The closed loop coil is electrically independent of the static magnetic field coil, and includes a winding portion including the high-temperature superconducting wire wound around the central axis and a shorting circuit that shorts the winding portion with the high-temperature superconducting wire.

### CROSS-REFERENCE TO RELATED APPLICATIONS

This application is based upon and claims the benefit of priority from Japanese Patent Application No. 2025-063130, filed Apr. 7, 2025, the entire contents of which are incorporated herein by reference.

### FIELD

Embodiments described herein relate generally to a superconducting magnet apparatus and a magnetic resonance imaging apparatus.

### BACKGROUND

High-temperature superconducting magnets can be considered to operate either in a persistent current mode or in a driven. In the persistent current mode, a superconducting coil is excited by an excitation power supply, and then a persistent current switch is turned on, so that a current is maintained in the superconducting coil. In the persistent current mode, an extremely low electrical resistance is required for connections of wires of the superconducting coil to prevent current attenuation due to electrical resistance, and superconducting connections are essential. However, superconducting connection technology for high-temperature superconducting wires used for the superconducting coil is still under development, and thus operation of a high-temperature superconducting magnet in the persistent current mode is difficult. In the driven, since a certain amount of electrical resistance does not affect accuracy, normal solder connections can be used. Magnetic resonance imaging (MRI) requires high magnetic field homogeneity, and thus also requires high accuracy for the excitation power supply. However, high-precision excitation power supplies are expensive and large in size, which pose a barrier to the practical application of high-temperature superconducting MRI.

### BRIEF DESCRIPTION OF THE DRAWINGS

FIG. 1 is a diagram illustrating a configuration example of a magnetic resonance imaging apparatus according to the present embodiment;

FIG. 2 is a diagram illustrating a schematic cross-sectional view of a superconducting magnet apparatus according to the present embodiment;

FIG. 3 is a diagram illustrating a mechanism for reducing magnetic field fluctuation by a closed loop coil;

FIG. 4 is a diagram illustrating a schematic cross-sectional view of a superconducting magnet apparatus according to a first modified embodiment;

FIG. 5 is a diagram illustrating a schematic cross-sectional view of a superconducting magnet apparatus according to a second modified embodiment;

FIG. 6 is a diagram comparing a magnetic field correction effect of a winding portion between the first modified embodiment and the second modified embodiment;

FIG. 7 is a diagram illustrating a schematic cross-sectional view of a superconducting magnet apparatus according to a third modified embodiment;

FIG. 8 is a diagram illustrating a schematic cross-sectional view of a superconducting magnet apparatus according to a fourth modified embodiment;

FIG. 9 is a diagram illustrating a schematic cross-sectional view of a superconducting magnet apparatus according to a fifth modified embodiment;

FIG. 10 is a diagram illustrating a schematic cross-sectional view of a superconducting magnet apparatus according to a sixth modified embodiment;

FIG. 11 is another diagram illustrating a schematic cross-sectional view of a superconducting magnet apparatus according to the sixth modified embodiment.

### DETAILED DESCRIPTION

A superconducting magnet apparatus according to an embodiment includes a vacuum vessel, a radiation shield, a static magnetic field coil, and a closed loop coil. The radiation shield is accommodated in the vacuum vessel. The static magnetic field coil is accommodated in the radiation shield and includes a high-temperature superconducting wire that is wound around a central axis of the vacuum vessel and excited by receiving a current supplied from an excitation power supply. The closed loop coil is a closed loop coil electrically independent from the static magnetic field coil and includes a winding portion including the high-temperature superconducting wire wound around the central axis and a shorting circuit that shorts the winding portion with the high-temperature superconducting wire.

Various Embodiments will be described hereinafter with reference to the accompanying drawings.

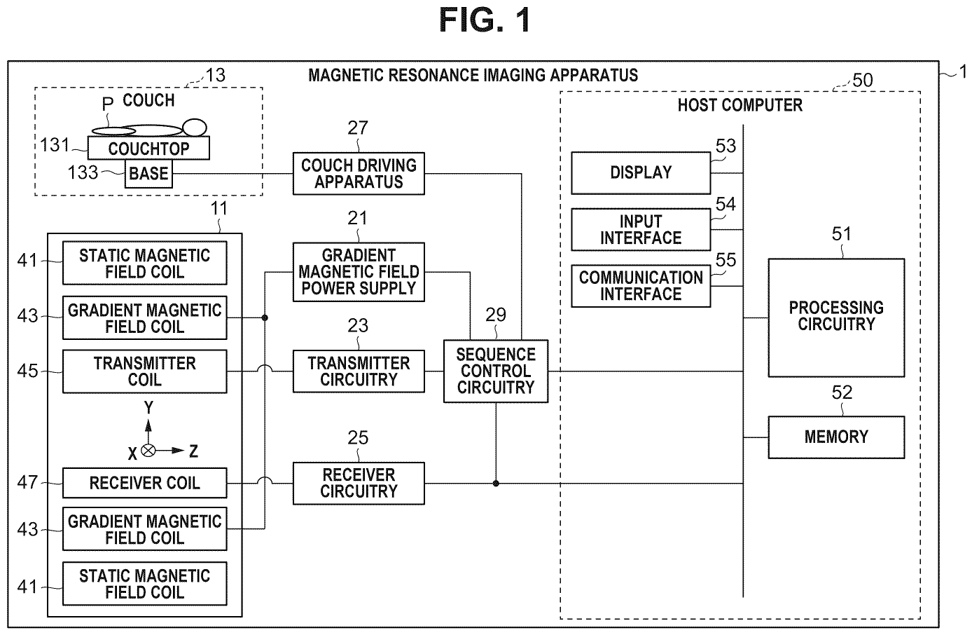

FIG. 1 is a diagram illustrating a configuration example of a magnetic resonance imaging apparatus 1 according to the present embodiment. As illustrated in FIG. 1, the magnetic resonance imaging apparatus 1 includes a superconducting magnet apparatus 11, a couch 13, a gradient magnetic field power supply 21, transmitter circuitry 23, receiver circuitry 25, a couch driving apparatus 27, sequence control circuitry 29, and a host computer 50.

The superconducting magnet apparatus 11 is also referred to as a gantry. The superconducting magnet apparatus 11 includes a static magnetic field coil 41 and a gradient magnetic field coil 43. The static magnetic field coil 41 and the gradient magnetic field coil 43 are accommodated in a housing of the superconducting magnet apparatus 11. A bore having a cylindrical shape is formed in the housing of the superconducting magnet apparatus 11. A transmitter coil 45 and a receiver coil 47 are disposed inside the bore of the superconducting magnet apparatus 11.

The static magnetic field coil 41 has a hollow, substantially cylindrical shape and generates a static magnetic field within the hollow portion. Here, the central axis of the static magnetic field coil 41 is defined as the Z-axis, an axis vertically perpendicular to the Z-axis is defined as the Y-axis, and an axis horizontally perpendicular to the Z-axis is defined as the X-axis. The X-axis, Y-axis, and Z-axis form an orthogonal three-dimensional coordinate system.

The gradient magnetic field coil 43 is a coil unit that is mounted inside the static magnetic field coil 41 and formed in a substantially hollow cylindrical shape. The gradient magnetic field coil 43 receives a current supplied from the gradient magnetic field power supply 21 and generates a gradient magnetic field. More specifically, the gradient magnetic field coil 43 includes three coils corresponding to the mutually orthogonal X-axis, Y-axis, and Z-axis. The three coils form the gradient magnetic fields in which magnetic field strength varies along the respective axes of the X-axis, Y-axis, and Z-axis. The gradient magnetic fields along the respective X-axis, Y-axis, and Z-axis are combined to form a slice selection gradient magnetic field Gs, a phase encoding gradient magnetic field Gp, and a frequency encoding gradient magnetic field Gr, which are orthogonal to one another, in a desired direction. The slice selection gradient magnetic field Gs is used to arbitrarily determine an imaging section (slice). The phase encoding gradient magnetic field Gp is used to vary the phase of a magnetic resonance signal (hereinbelow, referred to as an MR signal) in accordance with a spatial position. The frequency encoding gradient magnetic field Gr is used to vary the frequency of the MR signal in accordance with the spatial position. In the following description, it is assumed that the gradient direction of the slice selection gradient magnetic field Gs is the Z-axis, the gradient direction of the phase encoding gradient magnetic field Gp is the Y-axis, and the gradient direction of the frequency encoding gradient magnetic field Gr is the X-axis.

The gradient magnetic field power supply 21 supplies a current to the gradient magnetic field coil 43 according to a sequence control signal from the sequence control circuitry 29. The gradient magnetic field power supply 21 supplies a current to the gradient magnetic field coil 43 to cause the gradient magnetic field coil 43 to generate the gradient magnetic fields along the respective axes of the X-axis, the Y-axis and the Z-axis. The gradient magnetic fields are superimposed on the static magnetic field formed by the static magnetic field coil 41 and applied to a subject P.

The transmitter coil 45 is disposed, for example, inside the gradient magnetic field coil 43 and generates a high radio frequency pulse (hereinbelow, referred to as an RF pulse) by receiving a current supplied from the transmitter circuitry 23.

The transmitter circuitry 23 supplies a current to the transmitter coil 45 to apply the RF pulse to the subject P via the transmitter coil 45 in order to excite target protons present in the subject P. The RF pulse oscillates at a resonance frequency specific to the target protons and excites the target protons. The excited target protons generate an MR signal, and the generated MR signal is detected by the receiver coil 47. The transmitter coil 45 is, for example, a whole-body coil (WB coil). The whole-body coil may be used as a transmitter/receiver coil.

The receiver coil 47 receives the MR signal generated from the target protons present in the subject P in response to the action of an RF magnetic field pulse. The receiver coil 47 includes a plurality of receiver coil elements capable of receiving an MR signal. The received MR signal is supplied to the receiver circuitry 25 via wire or wirelessly. Although not illustrated in FIG. 1, the receiver coil 47 includes a plurality of receiver channels implemented in parallel. The receiver channels each include a receiver coil element that receives the MR signal, an amplifier that amplifies the MR signal, and the like. The MR signal is output for each of the receiver channels. The total number of the receiver channels may be the same as the total number of the receiver coil elements, or the total number of the receiver channels may be greater than or less than the total number of the receiver coil elements.

The receiver circuitry 25 receives the MR signal generated from the excited target protons via the receiver coil 47. The receiver circuitry 25 performs signal processing on the received MR signal to generate a digital MR signal. The digital MR signal can be represented in k-space, which is defined by spatial frequency. Thus, hereinbelow, the digital MR signal is referred to as k-space data. The k-space data is a type of raw data to be used for image reconstruction. The k-space data is supplied to the host computer 50 via wire or wirelessly.

The above-described transmitter coil 45 and receiver coil 47 are merely examples. Instead of the transmitter coil 45 and the receiver coil 47, a transmitter/receiver coil having a transmission function and a reception function may be used. Further, the transmitter coil 45, the receiver coil 47, and the transmitter/receiver coil may be combined.

The couch 13 is installed adjacent to the superconducting magnet apparatus 11. The couch 13 includes a couchtop 131 and a base 133. The subject P is placed on the couchtop 131. The base 133 supports the couchtop 131 such that it can slide along each of the X-axis, Y-axis, and Z-axis. The couch driving apparatus 27 is accommodated in the base 133. The couch driving apparatus 27 moves the couchtop 131 under the control of the sequence control circuitry 29. The couch driving apparatus 27 may include any motor such as a servo motor or a stepping motor.

The sequence control circuitry 29 includes, as hardware resources, a processor such as a central processing unit (CPU) or a micro processing unit (MPU) and a memory such as a read only memory (ROM) or a random access memory (RAM). The sequence control circuitry 29 synchronously controls the gradient magnetic field power supply 21, the transmitter circuitry 23, and the receiver circuitry 25 based on imaging conditions set by processing circuitry 51, executes MR imaging on the subject P in accordance with a pulse sequence corresponding to the imaging conditions, and collects the k-space data regarding the subject P.

As illustrated in FIG. 1, the host computer 50 is a computer that includes the processing circuitry 51, a memory 52, a display 53, an input interface 54, and a communication interface 55.

The processing circuitry 51 includes a processor such as a CPU as a hardware resource. The processing circuitry 51 functions as a central component of the magnetic resonance imaging apparatus 1. For example, the processing circuitry 51 automatically or manually sets the imaging conditions. Further, the processing circuitry 51 reconstructs an MR image regarding the subject P based on the k-space data collected via the receiver circuitry 25. Furthermore, the processing circuitry 51 is also capable of performing various types of processing on the MR image, such as rendering processing, image recognition, and image analysis.

The memory 52 is a storage device, such as a hard disk drive (HDD), a solid state drive (SSD), or an integrated circuit memory device, that stores various information. The memory 52 may also be a driving apparatus or the like that reads and writes various types of information from and to a portable storage medium such as a compact disk (CD)-ROM drive, a digital versatile disk (DVD) drive, or a flash memory. For example, the memory 52 stores imaging conditions, k-space data, MR images, control programs, and the like.

The display 53 displays various types of information. For example, the display 53 displays an MR image, an imaging condition setting screen, and the like. As the display 53, for example, a cathode ray tube (CRT) display, a liquid crystal display, an organic electroluminescence (EL) display, a light-emitting diode (LED) display, a plasma display, or any other display known in the art can be used as appropriate.

The input interface 54 includes an input device that receives various commands from an operator. As the input device, a keyboard, a mouse, various switches, a touch screen, a touch pad, and the like can be used. The input device is not limited to one equipped with a physical operation component such as a mouse and a keyboard. For example, electrical signal processing circuitry that receives an electrical signal corresponding to an input operation from an external input device provided separately from the magnetic resonance imaging apparatus 1 and outputs the received electrical signal to various circuits is also included in the examples of the input interface 54. The input interface 54 may also be an audio recognition apparatus that converts an audio signal collected by a microphone into an instruction signal.

The communication interface 55 is an interface that connects the magnetic resonance imaging apparatus 1 to a workstation, a picture archiving and communication system (PACS), a hospital information system (HIS), a radiology information system (RIS), and other systems via a local area network (LAN) or the like. A network interface (IF) transmits and receives various types of information to and from the workstation, PACS, HIS, and RIS of a connected destination.

The above-described configuration is an example, and the present embodiment is not limited to this. For example, the sequence control circuitry 29 may be incorporated in the host computer 50. The sequence control circuitry 29 and the processing circuitry 51 may be mounted on the same substrate.

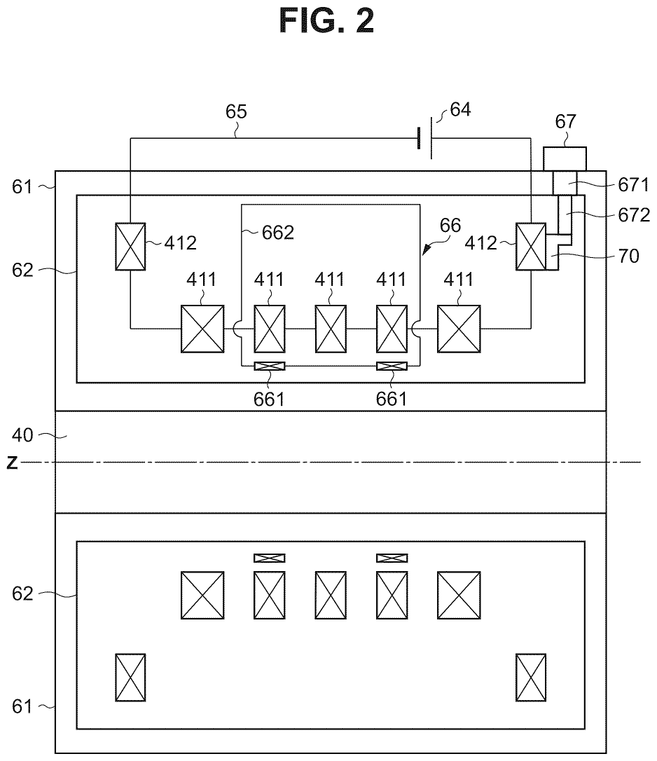

FIG. 2 is a diagram illustrating a schematic cross-sectional view of the superconducting magnet apparatus 11 according to the present embodiment. FIG. 2 illustrates only components necessary for the present embodiment, and, for example, the gradient magnetic field coil, the transmitter coil, a shim coil, and the like are omitted from the illustration. This also applies to the other drawings. In addition, the components illustrated in FIG. 2 and the other drawings, and the geometric relationships, such as positions and sizes, among the components are merely examples.

As illustrated in FIG. 2, the superconducting magnet apparatus 11 includes a vacuum vessel 61 having a cylindrical shape inside a gantry cover, which is not illustrated. A subject is placed in a cylindrical space (bore) 40 defined by the vacuum vessel 61. A magnetic field is applied to the bore 40, and a region of the bore 40 having relatively good spatial homogeneity is set as an imaging region. The central axis of the bore 40 is assumed to coincide with the Z-axis. The vacuum vessel 61 is a vessel capable of maintaining a vacuum therein.

A radiation shield 62 having a cylindrical shape is accommodated in the vacuum vessel 61. The radiation shield 62 is a structure formed of sheet metal parts made of aluminum, copper, or the like. The radiation shield 62 reduces heat intrusion due to radiation from outside of the radiation shield 62 to the inside thereof.

A static magnetic field coil 41i (i is 1 or 2) is accommodated in the radiation shield 62. The static magnetic field coil 41i includes a winding portion (hereinbelow, referred to as a static magnetic field winding portion) 411 for generating a static magnetic field in the bore 40 and a winding portion (hereinbelow, referred to as a shielding winding portion) 412 for generating a shielding magnetic field that reduces a leakage magnetic field outside the superconducting magnet apparatus 11. Two shielding winding portions 412 are disposed at both end portions of the vacuum vessel 61 and the radiation shield 62 in a Z-axis direction. One or a plurality of static magnetic field winding portions 411 is disposed between the two shielding winding portions 412 in the Z-axis direction. Hereinbelow, when the static magnetic field winding portion 411 and the shielding winding portion 412 are not distinguished from each other, they are collectively referred to as the static magnetic field coil 41.

The static magnetic field coil 41 includes a high-temperature superconducting wire wound around the central axis Z of the vacuum vessel 61. A “winding portion” according to the present embodiment refers to a portion of a wire, such as a high-temperature superconducting wire, that is formed by winding the wire around the central axis Z with one or more turns. The winding direction of the high-temperature superconducting wire is the same among the plurality of static magnetic field winding portions 411. The winding direction of the high-temperature superconducting wire is also the same among a plurality of shielding winding portions 412. The winding directions of the static magnetic field winding portion 411 and the shielding winding portion 412 are opposite to each other.

The high-temperature superconducting wire refers to a wire having a higher critical temperature than that of a low-temperature superconducting wire, which has, as its critical temperature, an ultralow temperature close to absolute zero (0 K or −273° C.). The critical temperature of the high-temperature superconducting wire may be 25 K or higher. As the high-temperature superconducting wire, for example, a rare earth barium copper oxide (REBCO) wire formed of a rare earth based superconductor including an element such as yttrium or gadolinium may be used. It is known that the REBCO wire can maintain a superconducting state even at 77 K. As an example, the REBCO wire is formed by depositing an intermediate layer on a flexible metal tape, forming a REBCO layer on the intermediate layer, and forming a protective layer of silver or the like on the REBCO layer. The high-temperature superconducting wire according to the present embodiment is not limited to a REBCO wire, and a wire formed of a superconductor including bismuth or any other element may also be used.

The static magnetic field coil 41 is included in an excitation circuit 65 that is connected to an excitation power supply 64. The excitation power supply 64 is disposed outside the vacuum vessel 61. The excitation power supply 64 supplies an excitation current to the static magnetic field coil 41 via the excitation circuit 65. The static magnetic field coil 41 is excited by receiving the excitation current and generates a static magnetic field. The excitation circuit 65 operates in a driven in which the static magnetic field coil 41 is connected to the excitation power supply 64 to circulate the excitation current through the excitation circuit 65. The excitation circuit 65 may be formed of an arbitrary wire.

The radiation shield 62 includes a closed loop coil 66 that is electrically independent of the static magnetic field coil 41. The closed loop coil 66 includes a winding portion (hereinbelow, referred to as a canceling winding portion) 661 that includes a high-temperature superconducting wire wound around the central axis Z and a shorting circuit 662 that shorts the canceling winding portion 661 with the high-temperature superconducting wire. The number of the canceling winding portions 661 may be one or more. The shorting circuit 662 is not connected to the excitation power supply 64 or other power supplies, and is connected to the canceling winding portion 661 to form a closed loop. The canceling winding portion 661 generates, by electromagnetic induction, a magnetic flux that reduces magnetic field fluctuations caused by the excitation power supply 64 that supplies a current to the static magnetic field coil 41 or caused by a magnetic material present outside the vacuum vessel 61. Both the static magnetic field winding portion 411 and the canceling winding portion 661 are wound to surround the bore 40. In other words, the static magnetic field winding portion 411 and the canceling winding portion 661 are arranged such that respective coil axes of the static magnetic field winding portion 411 and the canceling winding portion 661 are parallel to the Z-axis. Accordingly, a magnetic field formed by the canceling winding portion 661 can be superimposed on a magnetic field formed by the static magnetic field winding portion 411.

The vacuum vessel 61 is provided with a refrigerator 67. The static magnetic field coil 41 and the closed loop coil 66 are maintained in a superconducting state by being cooled by the refrigerator 67. The cooling method by the refrigerator 67 is not particularly limited. For example, the refrigerator 67 includes two cooling stages, and in order to maintain the high-temperature superconducting wire in a superconducting state, the radiation shield 62 is cooled by a first cooling stage 671, and the static magnetic field coil 41 is cooled by a second cooling stage 672 via a heat transfer material 70 made of high-purity aluminum or oxygen-free copper. The closed loop coil 66 is cooled by being thermally connected to at least one of the radiation shield 62 and the static magnetic field coil 41. Accordingly, the closed loop coil 66 is maintained in a superconducting state.

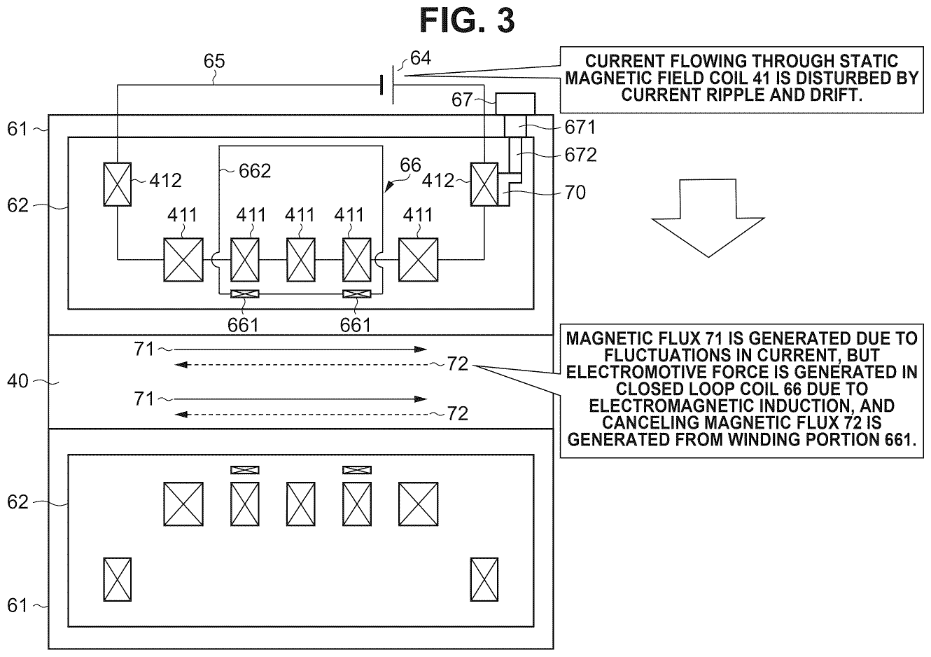

FIG. 3 is a diagram illustrating a mechanism for reducing magnetic field fluctuations by the closed loop coil 66. An excitation current is supplied from the excitation power supply 64 to the static magnetic field coil 41, thereby exciting the static magnetic field coil 41. A fluctuating component of the excitation current, such as a current ripple and drift, may be generated by the excitation power supply 64. This tendency is pronounced in a low-cost excitation power supply 64 having low current stability. When fluctuations occur in the excitation current, the current flowing through the static magnetic field coil 41 becomes temporally disturbed. Due to such fluctuations in the excitation current, a magnetic flux (hereinbelow, referred to as a fluctuating magnetic flux) 71 that penetrates the static magnetic field winding portion 411 of the static magnetic field coil 41 is generated from the static magnetic field winding portion 411. The fluctuating magnetic flux 71 becomes a factor that disturbs the static magnetic field. Here, “ripple” refers to a pulsating component contained in a direct current, and “drift” refers to a phenomenon in which a gradual and continuous change occurs even though all conditions are maintained constant.

As illustrated in FIG. 3, both the static magnetic field winding portion 411 and the canceling winding portion 661 are wound to surround the bore 40, so that the fluctuating magnetic flux 71 generated from the static magnetic field winding portion 411 also penetrates the canceling winding portion 661. Based on the principle of electromagnetic induction, an electromotive force is generated in the closed loop coil 66 by the fluctuating magnetic flux 71 penetrating through the canceling winding portion 661, and a magnetic flux (hereinbelow, referred to as a canceling magnetic flux) 72 is generated from the canceling winding portion 661 in an opposite direction to the fluctuating magnetic flux 71. The canceling magnetic flux 72 cancels the fluctuating magnetic flux 71, and thus it is possible to improve the spatial homogeneity of the static magnetic field formed in the bore 40.

Since a magnetic field (hereinbelow, referred to as a fluctuating magnetic field) generated by the fluctuating magnetic flux 71 is very small, the number of turns of the canceling winding portion 661 can be significantly smaller than the number of turns of the static magnetic field winding portion 411. Further, an induced current flowing through the canceling winding portion 661 due to the generation of the fluctuating magnetic flux 71 is very small compared with a current flowing through the static magnetic field winding portion 411. Thus, even if a critical current decreases during superconducting connection of the high-temperature superconducting wire used for the closed loop coil 66, such a decrease can be tolerated. Therefore, the closed loop coil 66 can be implemented using existing superconducting connection technology for a high-temperature superconducting wire, such as a REBCO wire.

A fluctuating magnetic flux may also be generated in the shielding winding portion 412 due to the supply of the excitation current. Thus, in a case where it is necessary to cancel the fluctuating magnetic flux generated from the shielding winding portion 412, the canceling winding portion 661 may be provided inside or outside the static magnetic field winding portion 411 in a radial direction of the vacuum vessel 61, and may also be provided inside or outside the shielding winding portion 412. Accordingly, it is possible to reduce spatial inhomogeneity of the static magnetic field caused by the fluctuating magnetic flux. However, in a case where it is not necessary to cancel the fluctuating magnetic flux generated from the shielding winding portion 412, the canceling winding portion 661 is provided inside or outside the static magnetic field winding portion 411 in the radial direction of the vacuum vessel 61, but need not be provided inside or outside the shielding winding portion 412. Accordingly, it is possible to reduce the number of components of the high-temperature superconducting wire.

The number of canceling winding portions 661 provided in the closed loop coil 66 is not particularly limited and may be one or more. In a case where a plurality of canceling winding portions 661 is provided, it is desirable that the plurality of canceling winding portions 661 is connected in series. Connecting the plurality of canceling winding portions 661 in series can improve the spatial homogeneity of the canceling magnetic field compared with connecting them in parallel, and as a result, it is possible to reduce spatial distortion of the fluctuating magnetic field with high accuracy.

The distribution of the canceling winding portion 661 in the Z-axis direction is not particularly limited. For example, the canceling winding portion 661 may be provided locally by being wound relatively densely in the Z-axis direction, or may be provided globally by being wound relatively sparsely in the Z-axis direction.

According to the above-described embodiment, the superconducting magnet apparatus 11 according to the present embodiment includes the vacuum vessel 61, the radiation shield 62, the static magnetic field coil 41, and the closed loop coil 66. The radiation shield 62 is accommodated in the vacuum vessel 61. The static magnetic field coil 41 is accommodated in the radiation shield 62 and includes the high-temperature superconducting wire that is wound around the central axis Z of the vacuum vessel 61 and excited by receiving a current supplied from the excitation power supply 64. The closed loop coil 66 is a coil electrically independent of the static magnetic field coil 41 and includes the canceling winding portion 661 including the high-temperature superconducting wire wound around the central axis Z and the shorting circuit 662 that shorts the canceling winding portion 661 with the high-temperature superconducting wire.

According to the above-described configuration, it is possible to realize high-temperature superconductivity using the high-temperature superconducting wire. In addition, in a case where fluctuations occur in a current from the excitation power supply 64, a canceling magnetic flux for reducing the fluctuating magnetic flux generated from the static magnetic field coil 41 can be generated from the canceling winding portion 661. Accordingly, it is possible to improve the magnetic field homogeneity of the static magnetic field formed in the bore 40. Further, since the canceling magnetic flux can cancel the fluctuating magnetic flux, it is possible to use a low-cost excitation power supply 64 having a current accuracy at a degree at which the fluctuating magnetic flux occurs.

### First Modified Embodiment

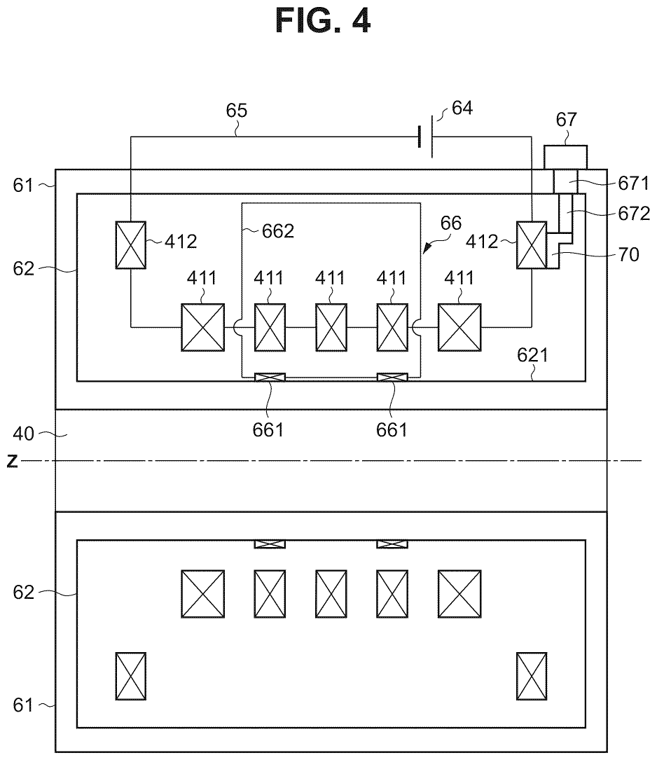

FIG. 4 is a diagram illustrating a schematic cross-sectional view of the superconducting magnet apparatus 11 according to a first modified embodiment. As illustrated in FIG. 4, a portion of the closed loop coil 66 according to the first modified embodiment is in contact with the radiation shield 62. Specifically, all or a portion of the canceling winding portion 661 of the closed loop coil 66 is wound around an inner surface 621 of an inner cylinder of the radiation shield 62. The inner surface 621 of the inner cylinder means the surface, among inner cylindrical surfaces of the radiation shield 62, on an internal space side of the radiation shield 62. The inner surface 621 of the inner cylinder is a portion closest to the bore 40 in the internal space of the radiation shield 62. By bringing the canceling winding portion 661 closer to the bore 40, it is possible to enhance a correction effect on the static magnetic field by the canceling magnetic field. The canceling winding portion 661 may be wound using the inner surface 621 of the inner cylinder of the radiation shield 62 as a winding frame. This can make it possible to form the canceling winding portion 661 more easily than a case where a winding frame is prepared separately.

### Second Modified Embodiment

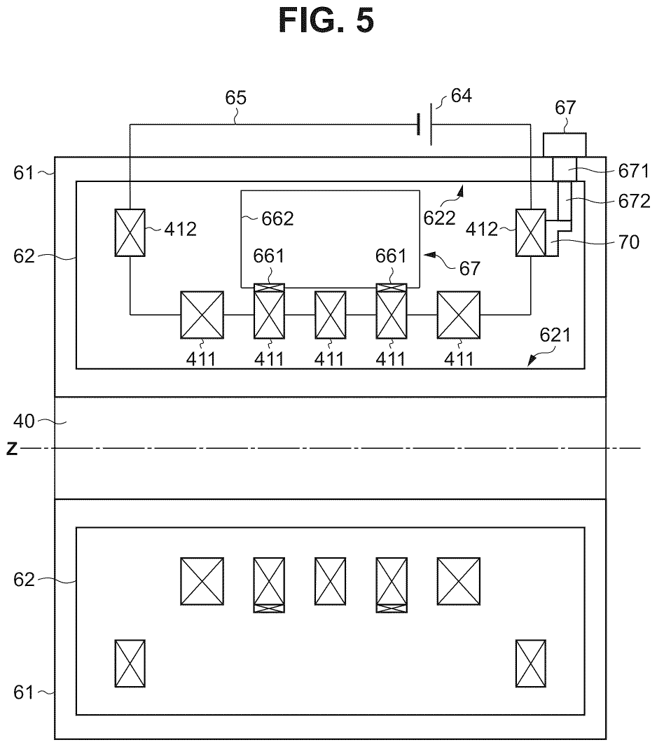

FIG. 5 is a diagram illustrating a schematic cross-sectional view of the superconducting magnet apparatus 11 according to a second modified embodiment. As illustrated in FIG. 5, all or a portion of the closed loop coil 66 according to the second modified embodiment is attached to an outer circumferential surface of the static magnetic field coil 41, specifically, an outer circumferential surface of the static magnetic field winding portion 411. The outer peripheral surface means the surface, among the peripheral surfaces of the static magnetic field winding portion 411, on an inner surface 622 side of an outer cylinder of the radiation shield 62. According to the second modified embodiment, since it is not necessary to dispose the canceling winding portion 661 between the static magnetic field winding portion 411 and the inner surface 621 of the inner cylinder of the radiation shield 62, it is possible to increase a diameter of the bore 40 as compared with the first modified embodiment in which the canceling winding portion 661 is disposed between the static magnetic field winding portion 411 and the inner surface 621 of the inner cylinder.

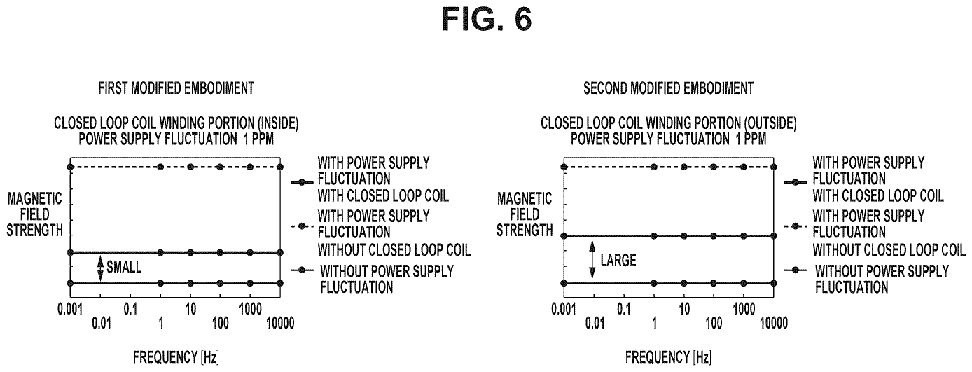

Here, the magnetic field correction effect by the canceling winding portion 661 is compared between the first modified embodiment and the second modified embodiment with reference to FIG. 6. A left diagram in FIG. 6 is a graph illustrating the correction effect according to the first modified embodiment, and a right diagram in FIG. 6 is a graph illustrating the correction effect according to the second modified embodiment. In both diagrams, the vertical axis represents magnetic field strength, and the horizontal axis represents frequency [Hz]. FIG. 6 illustrates graphs of results obtained by simulating magnetic field strength in a homogeneous magnetic field space in the bore 40 when the fluctuation of the excitation current from the excitation power supply 64 is 1 ppm and the frequency of the excitation current is varied from 0.001 Hz to 10,000 Hz.

For each of the first modified embodiment and the second modified embodiment, simulations were conducted for three types: (i) with power supply fluctuation and with a closed-loop coil, (ii) with power supply fluctuation and without a closed-loop coil, and (iii) without power supply fluctuation. A smaller difference between the line of (i) and the line of (iii) indicates a higher correction effect. As can be seen by comparing the left and right diagrams in FIG. 6, in the first modified embodiment where the canceling winding portion 661 is closer to the bore 40, the difference between the line of (i) and the line of (iii) is smaller, and it can be understood that the magnetic field correction effect is greater. In the second modified embodiment as well, since the line of (i) is closer to the line of (iii) than to the line of (ii), a certain degree of the correction effect is recognized.

### Third Modified Embodiment

As illustrated in FIG. 3, an electromotive force is generated in the closed loop coil 66 due to the generation of the fluctuating magnetic flux 71, and thus an induced current flows through the closed loop coil 66. Since the closed loop coil 66 is formed of the high-temperature superconducting wire and maintained in the superconducting state within the vacuum vessel 61, the induced current can circulate through the closed loop coil 66 without attenuation. The superconducting magnet apparatus 11 according to a third modified embodiment includes a mechanism for eliminating the induced current circulating through the closed loop coil 66. The superconducting magnet apparatus 11 according to the third modified embodiment will be described below.

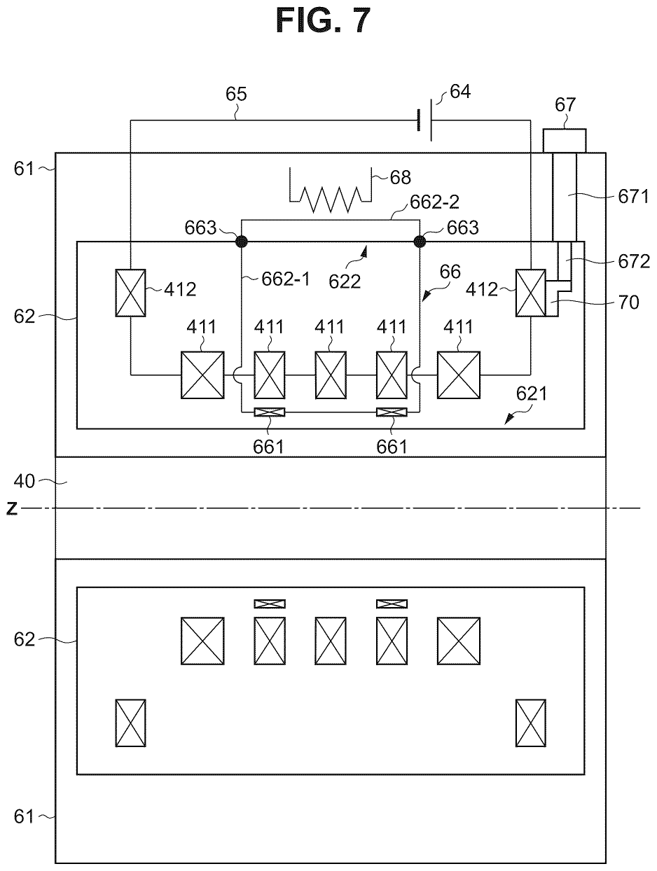

FIG. 7 is a diagram illustrating a schematic cross-sectional view of the superconducting magnet apparatus 11 according to the third modified embodiment. As illustrated in FIG. 7, a portion of the closed loop coil 66 according to the third modified embodiment may be provided in the radiation shield 62, and the remaining portion may be provided in an external space of the radiation shield 62 in the vacuum vessel 61.

The portion of the closed loop coil 66 is thermally connected to the radiation shield 62. Specifically, the shorting circuit 662 of the closed loop coil 66 includes contact points 663 and is thermally connected to the radiation shield 62 at the contact points 663. The number of the contact points 663 is not particularly limited and may be one or more; however, in FIG. 7, two contact points 663 are assumed.

A portion 662-1 of the shorting circuit 662 that is defined by the contact points 663 is located in the internal space of the radiation shield 62, and the remaining portion 662-2 is located in the external space or the internal space of the radiation shield 62 in the internal space of the vacuum vessel 61. The remaining portion 662-2 is connected to the canceling winding portion 661. Thus, the canceling winding portion 661 is accommodated in the radiation shield 62. The structure of the contact points 663 is not particularly limited. For example, a through hole may be formed in the radiation shield 62, and the high-temperature superconducting wire of the shorting circuit 662 may be passed through the through hole so as to contact the radiation shield 62. Accordingly, the shorting circuit 662 is brought into thermal contact with the radiation shield 62.

The high-temperature superconducting wire according to the present embodiment includes a wire of which a transition temperature from a superconducting state to a normal conducting state is equal to or higher than a first temperature. The first temperature is higher than a second temperature of the radiation shield 62 cooled by the first cooling stage 671 of the refrigerator 67. As one example, the high-temperature superconducting wire includes a wire of which the transition temperature from the superconducting state to the normal conducting state is 90 K or higher. The static magnetic field coil 41 that is cooled by the second cooling stage 672 of the refrigerator 67 is cooled to approximately 10 K to 30 K, and the radiation shield 62 is cooled to approximately 30 K to 60 K. A temperature of 90 K is an example of the first temperature, and a temperature in a range from 30 K to 60 K is an example of the second temperature. Since the shorting circuit 662 is in thermal contact with the radiation shield 62 at the contact points 663, it is assumed to have a temperature higher than the temperature of the static magnetic field coil 41 and close to the temperature of the radiation shield 62.

As illustrated in FIG. 7, the superconducting magnet apparatus 11 includes a heater 68, which is located in the external space of the radiation shield 62 inside the vacuum vessel 61. The heater 68 applies heat to the remaining portion 662-2 of the shorting circuit 662, thereby reducing the induced current flowing through the closed loop coil 66. Specifically, the heater 68 is connected to a power supply (hereinbelow, referred to as a heater power supply), which is not illustrated. The heater power supply supplies power to the heater 68 under the control of the processing circuitry 51 or the like. The heater 68 generates heat in accordance with the power supplied from the heater power supply. Specifically, the heater 68 generates an amount of heat necessary to raise the temperature of the high-temperature superconducting wire of the shorting circuit 662 from its current temperature to a temperature at which it can transition to the normal conducting state, for example, from 30 K to 90 K or higher. When the heater 68 applies heat to the shorting circuit 662, the high-temperature superconducting wire of the shorting circuit 662 transitions to the normal conducting state, and an electrical resistance is generated in the high-temperature superconducting wire. Due to the electrical resistance, the induced current flowing through the shorting circuit 662 is attenuated and eventually disappears.

The timing of applying heat by the heater 68 is not particularly limited. For example, a start command may be automatically supplied from the processing circuitry 51 to the heater power supply during a time period in which MR imaging is not being performed. Alternatively, the processing circuitry 51 may supply the start command to the heater power supply during an arbitrary time period, which is designated by an operator or the like via the input interface 54. Upon receiving the start command, the heater power supply supplies power to the heater 68, thereby enabling the heater 68 to apply heat to the portion 662-1 of the shorting circuit 662.

As described above, according to the third modified embodiment, since the shorting circuit 662 is in thermal contact with the radiation shield 62, the amount of heat required to raise the temperature of the high-temperature superconducting wire of the shorting circuit 662 to a temperature at which it can transition to the normal conducting state is smaller than in a case where the shorting circuit 662 is not in thermal contact with the radiation shield 62. Accordingly, the amount of heat generated by the heater 68 can be reduced, thereby reducing the degree of increase in the temperature of the static magnetic field coil 41 due to the heat generated from the heater 68. Further, it is also possible to reduce the power consumption of the heater 68 and to shorten the time until the induced current disappears.

Although it is assumed that the contact points 663 are insulated, the configuration is not limited thereto, and the shorting circuit 662 and the radiation shield 62 may be in electrical contact with each other. This is because the closed loop coil 66 is a circuit formed of a superconducting material, which is a high-temperature superconducting wire, and having zero electrical resistance, and it is considered that a current does not flow from the closed loop coil 66 to the radiation shield 62 even if the closed loop coil 66 is electrically connected to the radiation shield 62. Further, in the above descriptions, it has been described that the contact points 663 are in thermal contact with the radiation shield 62, the portion 662-1 of the shorting circuit 662 is provided in the internal space of the radiation shield 62, and the heater 68 and the remaining portion 662-2 are provided in the external space of the radiation shield 62. However, as long as the contact points 663 are in thermal contact with the radiation shield 62, the heater 68 and the remaining portion 662-2 may be provided in the internal space of the radiation shield 62.

### Fourth Modified Embodiment

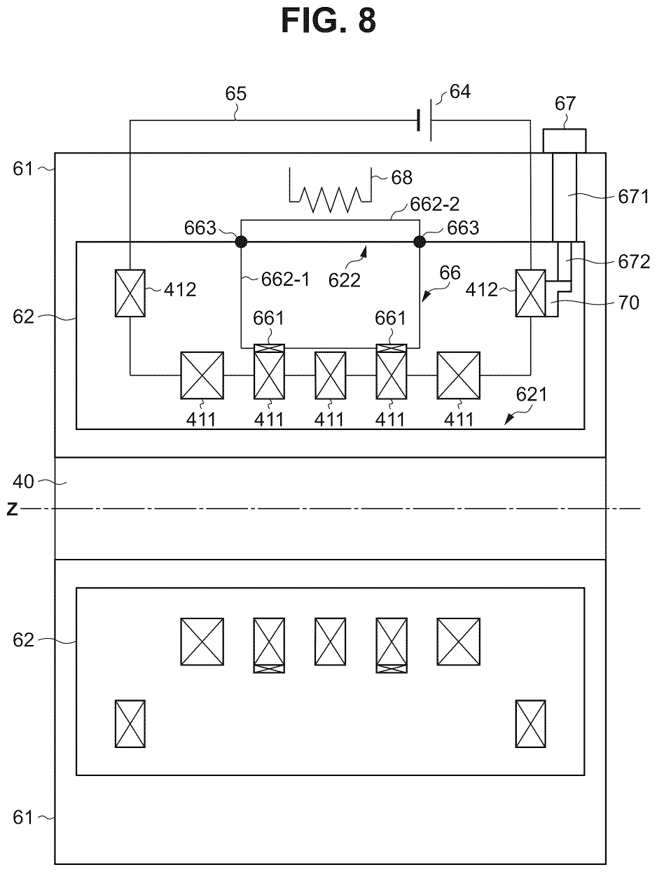

FIG. 8 is a diagram illustrating a schematic cross-sectional view of the superconducting magnet apparatus 11 according to a fourth modified embodiment. As illustrated in FIG. 8, the superconducting magnet apparatus 11 according to the fourth modified embodiment includes the canceling winding portion 661 attached to the static magnetic field coil 41 as in the second modified embodiment, and also includes a mechanism for applying heat to the closed loop coil 66 by the heater 68 as in the third modified embodiment. With this configuration, it is possible to enlarge the diameter of the bore 40 as in the second modified embodiment while reducing the induced current flowing through the closed loop coil 66 as in the third modified embodiment.

### Fifth Modified Embodiment

The excitation circuit 65 according to the above-described embodiments has operates in the driven in which the static magnetic field coil 41 is connected to the excitation power supply 64 to circulate the excitation current through the excitation circuit 65. The excitation circuit 65 according to a fifth modified embodiment includes a persistent current switch that switches between the persistent current mode in which the static magnetic field coil 41 is disconnected from the excitation power supply 64 to circulate a current through the excitation circuit 65, and the driven in which the static magnetic field coil 41 is connected to the excitation power supply 64 to circulate the excitation current through the excitation circuit 65. The superconducting magnet apparatus 11 according to the fifth modified embodiment will be described below.

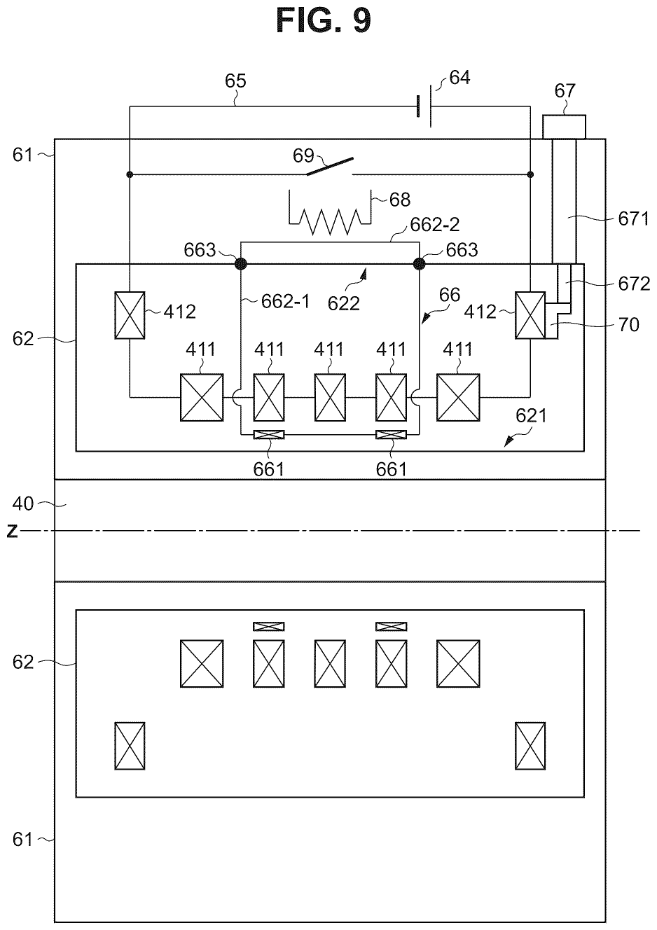

FIG. 9 is a diagram illustrating a schematic cross-sectional view of the superconducting magnet apparatus 11 according to the fifth modified embodiment. As illustrated in FIG. 9, the excitation circuit 65 is provided with a persistent current switch 69 in the external space of the radiation shield 62 in the internal space of the vacuum vessel 61. The persistent current switch 69 and the static magnetic field coil 41 are connected in parallel via the high-temperature superconducting wire. The type of the persistent current switch 69 is not particularly limited, and can be realized by, for example, a mechanical type, a thermal type, or other types.

The persistent current switch 69 is connected to the processing circuitry 51 via wiring, which is not illustrated. In transitioning to an energized mode, the processing circuitry 51 supplies an OFF signal to the persistent current switch 69 to open the persistent current switch 69, and also supplies an ON signal to the excitation power supply 64 to connect the static magnetic field coil 41 to the excitation power supply 64. Accordingly, the excitation current circulates through the excitation circuit 65 that passes through the static magnetic field coil 41 and the excitation power supply 64.

In transitioning to the persistent current mode, the processing circuitry 51 supplies an ON signal to the persistent current switch 69 to close the persistent current switch 69, and also supplies an OFF signal to the excitation power supply 64 to disconnect the static magnetic field coil 41 from the excitation power supply 64. Accordingly, a persistent current circulates through the excitation circuit 65 that passes through the static magnetic field coil 41 and the persistent current switch 69.

Whether an operation mode of the excitation circuit 65 during MR imaging is set to the driven or the persistent current mode can be arbitrarily selected by an operator according to the performance of the excitation power supply 64, the high-temperature superconducting wire and the like. For example, in a case where it is assumed that the performance of the excitation power supply 64 or the performance of the high-temperature superconducting wire is insufficient and maintaining the persistent current is difficult, it is desirable to set the operation mode to the driven. In this case, the processing circuitry 51 transitions the excitation circuit 65 to the energized mode to perform MR imaging. In the case of the persistent current mode, the processing circuitry 51 sets the excitation circuit 65 to the energized mode to excite the static magnetic field coil 41, and then transitions to the persistent current mode to perform MR imaging.

The excitation power supply 64 is not operated in the persistent current mode, so that magnetic field fluctuations resulting from fluctuations in the excitation current do not occur. However, the magnetic field fluctuations may also be caused by movement of a magnetic substance, such as an automobile or an elevator, around the superconducting magnet apparatus 11. The closed loop coil 66 can reduce the fluctuating magnetic field caused by the movement of the magnetic substance using the canceling magnetic field.

The fifth modified embodiment can be combined with any of the above-described embodiments. For example, in a case where the persistent current switch 69 is provided, the heater 68 need not necessarily be provided, and in this case, the entire closed loop coil 66 may be accommodated in the radiation shield 62.

### Sixth Modified Embodiment

The superconducting magnet apparatus 11 according to a sixth modified embodiment has various variations regarding the arrangement of the static magnetic field winding portion 411 and the canceling winding portion 661.

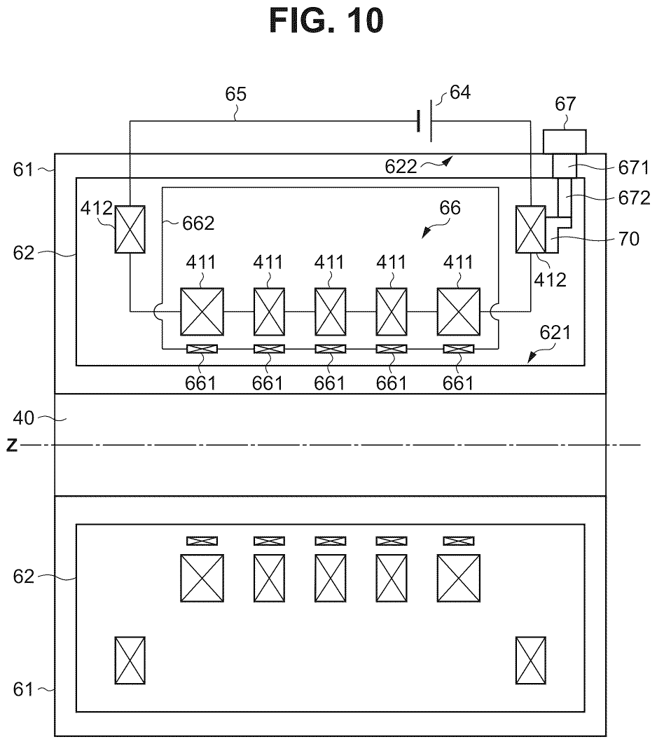

FIG. 10 is a diagram illustrating a schematic cross-sectional view of the superconducting magnet apparatus 11 according to the sixth modified embodiment. As illustrated in FIG. 10, the static magnetic field winding portion 411 and the canceling winding portion 661 are provided in a one-to-one correspondence. Specifically, one canceling winding portion 661 is provided for each of the five static magnetic field winding portions 411. As illustrated in FIG. 10, the canceling winding portion 661 may be disposed between the static magnetic field winding portion 411 and the inner surface 621 of the inner cylinder of the radiation shield 62, may be attached to the inner circumferential surface or the outer circumferential surface of the static magnetic field winding portion 411, or may be attached to the inner surface 621 of the inner cylinder of the radiation shield 62.

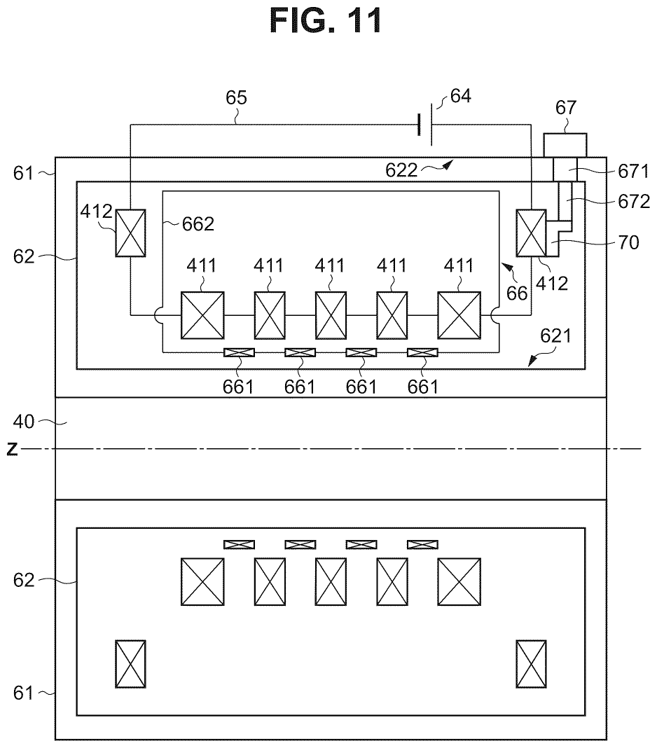

FIG. 11 is another diagram illustrating a schematic cross-sectional view of the superconducting magnet apparatus 11 according to the sixth modified embodiment. As illustrated in FIG. 11, the static magnetic field winding portion 411 and the canceling winding portion 661 are provided in a non-one-to-one correspondence. Specifically, one canceling winding portion 661 is disposed between adjacent two static magnetic field winding portions 411. As illustrated in FIG. 11, the canceling winding portion 661 may be disposed between the static magnetic field winding portion 411 and the inner surface 621 of the inner cylinder, or may be attached to the inner surface 621 of the inner cylinder of the radiation shield 62.

The arrangement of the static magnetic field winding portion 411 and the canceling winding portion 661 is not limited to two options of the one-to-one correspondence arrangement illustrated in FIG. 10 and the non-one-to-one correspondence arrangement illustrated in FIG. 11, and can be arbitrarily designed to accurately reduce the fluctuating magnetic field by the canceling magnetic field. As an example, at the end portions in the Z-axis direction, the static magnetic field winding portion 411 and the canceling winding portion 661 may be arranged in the one-to-one correspondence as illustrated in FIG. 10, and at the center portion in the Z-axis direction, the static magnetic field winding portion 411 and the canceling winding portion 661 may be arranged in the non-one-to-one correspondence as illustrated in FIG. 11. As another example, at the end portions in the Z-axis direction, the static magnetic field winding portion 411 and the canceling winding portion 661 may be arranged in the non-one-to-one correspondence as illustrated in FIG. 11, and at the center portion in the Z-axis direction, the static magnetic field winding portion 411 and the canceling winding portion 661 may be arranged in the one-to-one correspondence as illustrated in FIG. 10.

According to at least one of the embodiments described above, high-temperature superconductivity can be realized at a low cost while improving the magnetic field homogeneity.

The term “processor” used in the above description refers to a circuit such as a central processing unit (CPU), a graphics processing unit (GPU), an application specific integrated circuit (ASIC), and a programmable logic device (e.g., a simple programmable logic device [SPLD], a complex programmable logic device [CPLD], or a field programmable gate array [FPGA]). The processor implements the functions by reading out and executing a program stored in a storage circuit. Instead of storing the programs in the storage circuit, the programs may be directly built in the processor circuit. In such a case, the processor implements the functions by reading the built-in programs in its own circuit and executing the programs. On the other hand, in a case where the processor is, for example, an ASIC, instead of the program being stored in the storage circuit, the function is directly incorporated, as logic circuitry, into the processor circuit. The processors according to the exemplary embodiments are not limited to a single-circuit configuration. A plurality of independent circuits may be combined into a processor that implements the functions. Furthermore, the plurality of elements in FIG. 1 may be integrated into a single processor to realize the functions thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A superconducting magnet apparatus comprising:
a vacuum vessel;
a radiation shield accommodated in the vacuum vessel;
a static magnetic field coil accommodated in the radiation shield and including a high-temperature superconducting wire that is wound around a central axis of the vacuum vessel and excited by receiving a current supplied from an excitation power supply; and
a closed loop coil configured to be electrically independent of the static magnetic field coil, the closed loop coil including a winding portion including the high-temperature superconducting wire wound around the central axis and a shorting circuit that shorts the winding portion with the high-temperature superconducting wire.

2. The superconducting magnet apparatus according to claim 1, wherein a portion of the closed loop coil is in contact with the radiation shield.

3. The superconducting magnet apparatus according to claim 2, wherein all or a portion of the winding portion is wound around an inner surface of an inner cylinder of the radiation shield.

4. The superconducting magnet apparatus according to claim 2, wherein the portion is thermally connected to the radiation shield.

5. The superconducting magnet apparatus according to claim 2, wherein the shorting circuit includes a contact point and is thermally connected to the radiation shield at the contact point.

6. The superconducting magnet apparatus according to claim 5, further comprising a heater located in an external space of the radiation shield within an internal space of the vacuum vessel,
wherein the winding portion is accommodated in the radiation shield,
wherein a portion of the shorting circuit defined by the contact point is located in an internal space or an external space of the radiation shield,
wherein a remaining portion of the shorting circuit is located in the external space of the radiation shield within the internal space of the vacuum vessel, and
wherein the heater applies heat to the remaining portion of the shorting circuit and reduces an induced current flowing through the closed loop coil.

7. The superconducting magnet apparatus according to claim 2, wherein all or a portion of the winding portion is attached to an outer circumferential surface of the static magnetic field coil.

8. The superconducting magnet apparatus according to claim 2, further comprising a refrigerator configured to cool the static magnetic field coil and the radiation shield,
wherein the high-temperature superconducting wire includes a wire of which a transition temperature from a superconducting state to a normal conducting state is equal to or higher than a first temperature, and
wherein the first temperature is higher than a second temperature of the radiation shield cooled by the refrigerator.

9. The superconducting magnet apparatus according to claim 1,
wherein the static magnetic field coil is included in an excitation circuit that is connected to the excitation power supply, and
wherein the excitation circuit operates in a driven in which the static magnetic field coil is connected to the excitation power supply to circulate an excitation current through the excitation circuit.

10. The superconducting magnet apparatus according to claim 1,
wherein the static magnetic field coil is included in an excitation circuit that is connected to the excitation power supply, and
wherein the excitation circuit includes a persistent current switch that switches between a persistent current mode in which the static magnetic field coil is disconnected from the excitation power supply to circulate a current through the excitation circuit under a superconducting condition and a driven in which the static magnetic field coil is connected to the excitation power supply to circulate an excitation current through the excitation circuitry.

11. The superconducting magnet apparatus according to claim 1,
wherein the winding portion includes a plurality of winding portions, and
wherein the plurality of winding portions is connected in series in the shorting circuit.

12. The superconducting magnet apparatus according to claim 1, wherein the winding portion generates a magnetic flux that reduces fluctuations in a magnetic field caused by an excitation power supply that supplies a current to the static magnetic field coil by electromagnetic induction or caused by a magnetic substance present in an external space of the vacuum vessel.

13. The superconducting magnet apparatus according to claim 1, wherein the high-temperature superconducting wire includes a wire of which a transition temperature from a superconducting state to a normal conducting state is equal to or higher than 90 K.

14. The superconducting magnet apparatus according to claim 1, further comprising a refrigerator configured to cool the static magnetic field coil and the radiation shield,
wherein the static magnetic field coil is maintained in a superconducting state by being cooled by the refrigerator, and
wherein the closed loop coil is maintained in a superconducting state by being thermally connected to at least one of the static magnetic field coil and the radiation shield.

15. The superconducting magnet apparatus according to claim 1, wherein a number of turns of the winding portion is less than a number of turns of the static magnetic field coil.

16. The superconducting magnet apparatus according to claim 1,
wherein the static magnetic field coil includes a static magnetic field winding portion for generating a static magnetic field and a shielding winding portion for generating a shielding magnetic field to reduce a leakage magnetic field, and
wherein the winding portion is provided inside or outside the static magnetic field winding portion in a radial direction of the vacuum vessel and is not provided inside or outside the shielding winding portion.

17. A magnetic resonance imaging apparatus comprising:
the superconducting magnet apparatus according to claim 1;
a couch configured to support a couchtop on which a subject is placed;
control circuitry configured to control the superconducting magnet apparatus to perform magnetic resonance (MR) imaging on the subject;
receiver circuitry configured to receive an MR signal generated from the subject by the MR imaging; and
processing circuitry configured to reconstruct an MR image regarding the subject based on the received MR signal.
